(19) United States
(12) Patent Application Publication
(10) Pub. No.: US 2007/0162821 A1
(43) Pub. Date: Jul. 12, 2007

(54) Parity check matrix, method of generating parity check matrix, encoding method and error correction apparatus

(75) Inventors: Sung-hee Hwang, Suwon-si (KR); Hyun-jung Kim, Suwon-si (KR); Jin-seok Hong, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/590,820

(22) Filed: Nov. 1, 2006

(30) Foreign Application Priority Data
Dec. 15, 2005 (KR) 2005-124111

(51) Int. Cl. H03M 13/00

(52) U.S. Cl. 714/758

(57) ABSTRACT

A parity check matrix making it possible to encode through decoding, a method of generating a parity check matrix, an encoding method and an error correction apparatus including defining an M×N parity check matrix H=[Hₘ|Hₚ], and generating an M×M matrix as a sub-matrix Hₚ wherein all row vectors are linearly independent, a set A of all of the row vectors is a union set of non-empty subsets A₁, A₂, . . . , Aₖ (1≦k≦M) that do not include intersection sets with each other, A₁ is a set of weight one row vectors, and Aᵢ (2≦i≦k) is a set of row vectors capable of deriving a weight one row vector by a linear combination with row vectors in a union set of the subsets A₁, . . . , Aᵢ₋₁ among the row vectors not included in the union set.

This application claims the benefit of Korean Patent Application No. 2005-124111, filed on Dec. 15, 2005, in the Korean Intellectual Property Office, the disclosure of which is incorporated herein by reference.

### BACKGROUND OF THE INVENTION

1. Field of the Invention

Aspects of the present invention relate to a parity check matrix, a method of generating a parity check matrix, an encoding method and en error correction apparatus, all of which are used for error correction.

2. Description of the Related Art

According to the high density of information storage media and data transmission, data playback per unit time or transmission quantity increase in a communication channel when transmitting data through wired, wireless, and/or optical communication devices. Therefore, many errors can occur when a channel situation worsens. For example, since more data can be stored in a high-density optical storage medium, more errors occur due to dust, scratches, fingerprints, etc. Additionally, since an amount of data transmission per unit time increases with high density data in wired/wireless communication, an amount of errors, which are contained in the data received with respect to a communication failure during the same time, relatively increases. An error correction method or an error correction code, which has a high error correction capability, is required according to the high-density data.

A soft iterative decoding method, such as a conventional Reed-Solomon (RS) code, in which error correction is not performed with hard values (for example, 0 or 1) of inputted bits, is used to perform error correction through repetitive correction by referring to soft values (for example, 0.2 or 0.9) of an inputted bit as an error correction code and a method such as turbo code decoding and low density parity check (LDPC) decoding. The soft value of the inputted bit can be represented with probability of the inputted hard value.

A linear block code, such as the RS code or the LDPC code, includes a parity check matrix, H, that satisfies HC^{T}=0 with respect to a given codeword vector, C. Additionally, there is a generator matrix, G, in the given H, which satisfies m*G=C. Here, m and C represent a message vector and a codeword vector, respectively. That is, the message vector, m, can be obtained by encoding through converting the message vector into the codeword vector with the generator matrix, G, and decoding the received codeword vector with the parity check matrix, H, in the linear block code. Accordingly, a separate additional hardware for encoding and decoding must be configured to apply the message vector to an optical storage medium or an actual system (i.e. wired/wireless communication systems, computer systems, etc.).

A method of performing the RS encoding and the RS decoding using a single RS decoder to reduce the hardware load is disclosed in U.S. Pat. No. 5,771,244. The reason that a single RS decoder can perform encoding is as follows. The RS decoder searches and corrects the error position and the value of the codeword vector through an algebraic method of the received codeword vector using the parity check matrix H, and uses an erasure correction method to perform a correction by obtaining the error position in advance during the encoding. The message vector becomes the codeword vector by adding additional information (i.e., parity). At this point, a portion where the parity is added is regarded as an error in advance, the message vector is determined, and the codeword vector is inputted into the RS decoder. Then, the RS decoder performs the encoding through the erasure correction about the received codeword vector to generate the actual parity vector about the message vector. However, there is a problem that this method cannot be applied to a system performing the decoding through iteration, such as the turbo code or the LDPC code.

### SUMMARY OF THE INVENTION

Aspects of the present invention provide a parity check matrix making it possible to encode through decoding, a method of generating a parity check matrix, an encoding method, and an error correction apparatus.

According to an aspect of the present invention, there is provided a parity check matrix for an error correction, wherein the parity check matrix, H, is an M×N matrix, H=[Hₘ|Hₚ], wherein Hₘ is an M×(N−M) sub-matrix and Hₚ is an M×M sub-matrix; and all row vectors of the Hₚ sub-matrix are linearly independent, a set, A, of all the row vectors is a union set of subsets A₁, A₂, . . . , Aₖ (1≦k≦M) that do not include intersection sets with each other and are not empty sets, the subset, A₁, is a set of weight one row vectors among the elements of the set A, and the subset, Aᵢ (2≦i≦k), is a set of row vectors capable of deriving a weight one row vector by performing a linear combination with row vectors in the union set of the subsets A₁, . . . , Aᵢ, among the row vectors not included in the union set of the subsets A₁, . . . , Aᵢ₋₁.

The parity check matrix does not include four cycles.

According to another aspect of the present invention, there is provided a method of generating a parity check matrix for an error correction including: defining an M×N parity check matrix H=[Hₘ|Hₚ]; and generating an M×M matrix as a sub-matrix Hₚ wherein all row vectors are linearly independent, a set A of all the row vectors is a union set of subsets A₁, A₂, . . . , Aₖ (1≦k≦M) that do not include intersection sets with each other and are not empty sets, the subset A₁ is a set of weight one row vectors among the elements of the set A, and the subset Aᵢ (2≦i≦k) is a set of row vectors capable of deriving a weight one row vector by performing a linear combination with row vectors in the union set of the subsets A₁, . . . , Aᵢ₋₁ among the row vectors not included in the union set of the subsets A₁, . . . , Aᵢ₋₁.

According to yet another aspect of the present invention, there is provided an encoding method for an N−M dimension message vector including generating an M×N parity check matrix, and obtaining a parity vector of an M dimension to be added to the message vector through decoding using the generated parity check matrix.

The obtaining of the parity vector may further include correcting an error on the parity vector by performing a soft iterative decoding with inputs of the message vector and the parity vector set with 0s.

According to another aspect of the present invention, there is provided an error correction apparatus including a matrix generator generating M×N parity check matrix, and a decoder encoding a message vector of an N−M dimension by obtaining a parity vector of an M dimension to be added to the message vector of an N−M dimension through decoding using the generated parity check matrix, and decoding a received codeword vector.

The error correction apparatus may further include a decoder input processor outputting a codeword vector having a result of replacing 0s of the message vector with −1s and a parity vector set with 0s into the decoder during the encoding, wherein the decoder is a soft iterative decoder.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a sub-matrix, Hₚ, of an M×N parity check matrix, H=[Hₘ|Hₚ], according to an embodiment of the present invention;

FIG. 2 is a sub-matrix, Hₚ, of an M×N parity check matrix, H=[Hₘ|Hₚ], according to another embodiment of the present invention;

FIG. 3A is a sub-matrix, Hₚ, of an M×N parity check matrix, H=[Hₘ|Hₚ], according to still another embodiment of the present invention;

FIG. 3B is a sub-matrix, Hₚ, of an M×N parity check matrix, H=[Hₘ|Hₚ], according to another embodiment of the present invention;

FIG. 4A is a diagram illustrating a connection between a parity check node and a bit node of a sub-matrix, Hₚ, in FIG. 1, according to an embodiment of the present invention;

FIG. 4B is a diagram illustrating a connection between a parity check node and a bit node of a sub-matrix, Hₚ, in FIG. 2, according to another embodiment of the present invention;

FIG. 5 is a flowchart illustrating an encoding method by decoding according to an embodiment of the present invention;

FIG. 6 is a configuration diagram of an error correction apparatus according to an embodiment of the present invention; and

FIGS. 7A through 7D are diagrams to explain encoding processes according to an embodiment of the present invention

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Encoding is generally classified into systematic encoding and non-systematic encoding. In systematic encoding, original values are maintained in a message vector, and a codeword is generated by adding a parity vector. That is, a portion corresponding to a message vector of a codeword encoded using the systematic encoding method has the same values as an original message vector. On the other hand, in non-systematic encoding, the values of the message vector are changed into other values.

According to an aspect of the present invention, a parity check matrix making it possible to perform the systematic encoding by decoding is defined as follows.

The parity check matrix is defined as an M×N matrix, H, having an M number of linearly independent rows in a vector space of a growth factor, GF(2). Additionally, an M×M sub-matrix, Hₚ, of the matrix H is defined to have the following structure.

Definition 1: let's assume that a set of the M number of row vectors is A.

Definition 2: let's assume that a number of non-zero elements among each element of vectors is weight (i.e., the weight of a vector V=(1, 0, 0, 0, 1, 0, 0) is two).

Definition 3: let's assume that a set of elements with weight one among elements of a set A is A₁.

The subset A₁ of the set A is not an empty set.

If a difference set, B₁=A−A₁, of the set A and the set A₁ is not an empty set, the set B₁ includes a subset, A₂, of the set B₁ with vectors, and the subset A₂ is not an empty set. If a weight one vector can be obtained by a linear combination of v and the vectors of the A₁ with respect to an element vector v of the set B₁, the vector v is an element of A₂.

If a difference set B₂=A−(A₁ U A₂) is not an empty set, the set B₂ includes a subset A₃ of the set B₂with vectors, and A₃ is not an empty set. If a weight one vector can be obtained by a linear combination of v and A₁ U A₂vectors with respect to an element vector v of the set B₂, the vector v is an element of A₃.

Using the above formula, a variable, k, makes a difference set, Bₖ=A−(A₁ U A₂ U . . . U Aₖ), become an empty set (i.e. A=(A₁ U A₂ U . . . U Aₖ)), and is equal to or more than 1 and equal to or less than M.

The M number of row vectors of Hₚ are linearly independent.

To summarize, the parity check matrix is defined with the structure of an M×N matrix, H=[Hₘ|Hₚ]. In the M×M sub-matrix Hₚ of the M×N matrix H=[Hₘ|Hₚ], all row vectors are linearly independent, a set, A, of all the row vectors is a union set of subsets A₁, A₂, . . . , Aₖ (1≦k≦M) that do not include intersection sets mutually and are not empty sets, the subset A₁ is a set of weight one row vectors among the elements of the set A, and the subset Aᵢ (2≦i≦k) is a set of row vectors capable of deriving a weight one row vector through a linear combination with row vectors in the union set of the subset A₁, . . . , Aᵢ₋₁ among the row vectors not included in the union set of the subset A₁, . . . , Aᵢ₋₁. Additionally, it is desirable that the parity check matrix does not include four cycles. When the four cycles are included, performance of the parity check matrix is significantly reduced.

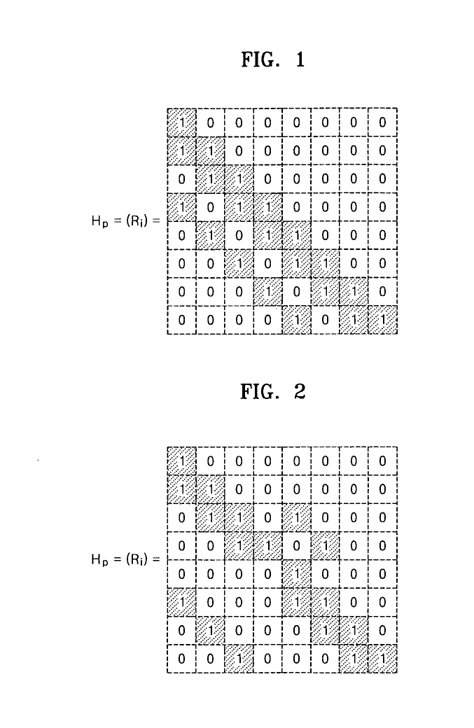

FIG. 1 is a sub-matrix, Hₚ, of an M×N parity check matrix, H=[Hₘ|Hₚ], according to an embodiment of the present invention. Referring to FIG. 1, M is 8 and Rᵢ (i=1, 2, . . . , 8) represents an i^{th} row vector. Also, k is 8, and Aᵢ has one row vector with respect to each i and is identical to {Rᵢ}.

FIG. 2 is a sub-matrix, Hₚ, of an M×N parity check matrix, H=[Hₘ|Hₚ], according to another embodiment of the present invention. Referring to FIG. 2, M is 8 and Rᵢ (i=1, 2, . . . , 8) represents an i^{th} row vector. Also, k is 4 and A₁={R₁, R₅}, A₂={R₂, R₆}, A₃={R₃, R₇}, A₄={R₄, R₈}.

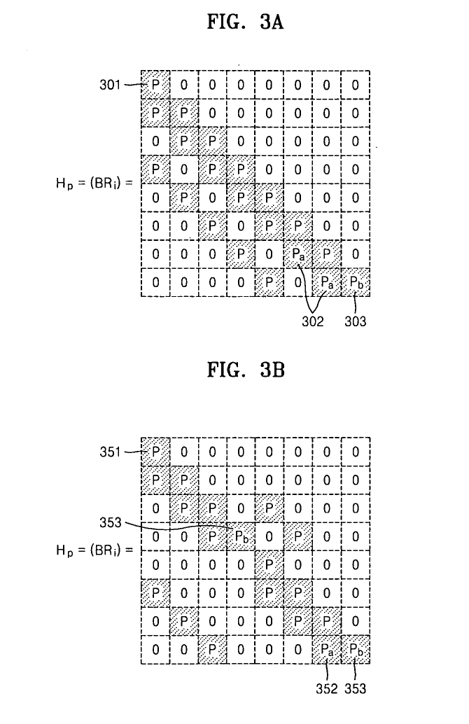

FIG. 3A is a sub-matrix, Hₚ, of an M×N parity check matrix, H=[Hₘ|Hₚ], according to still another embodiment of the present invention. FIG. 3B is a sub-matrix, Hₚ, of an M×N parity check matrix, H=[Hₘ|Hₚ], according to another of the present invention.

Referring to FIGS. 3A and 3B, M is 8*B and B is an integer greater than 1. That is, the sub-matrices, Hₚ, of FIGS. 1 and 2 are expanded into the sub-matrices, Hₚ, of FIGS. 3A and 3B, which respectively illustrate a sub-matrix, Hₚ, of H satisfying the definition according to an aspect of the present invention when the parity check matrix H is made of a block structure. BRᵢ (I=1, 2, . . . , 8) is a B×8*B. For example, BR₁ is B×8*B (P0 0 0 0 0 0 0) having a first B number of row vectors of H. P(301, 351) is a B×B unit matrix I or a permutation matrix of the B×B unit matrix I by row-shifting the B×B unit matrix I. It is desirable that a girth (the shortest cycle length in the matrix H) is more than 6 in the P(301, 351) obtained by row-shifting the B×B unit matrix I. That is, it is desirable that the shift value is determined in order not to have four cycles. Additionally, 0 represents B×B zero matrix in FIGS. 3A and 3B.

As illustrated in FIGS. 1 and 2, H includes at least one column vector with weight one. When there is a weight one column, the performance of the parity check matrix is more or less reduced due to the parity check matrix characteristics. When the Hₚ structure is designed with a B×B block structure as illustrated in FIGS. 3A and 3B, at least a B number of weight one columns is included. Since it is desirable to minimize the number of weight one columns, it is necessary that Pₐ (302, 352) includes a B×B matrix with weight one or two columns, and also P_{b} (303, 353) includes a B×B matrix satisfying the characteristics in FIG. 1 or FIG. 2.

When P_{b} is a permutation matrix of the B×B unit matrix I, Aᵢ={v|v=a row vector of BRᵢ}, where k=8 and i=1, 2, . . . , 8 in FIG. 3A, and there are a B number of weight one column vectors. In FIG. 3B, k=4, A₁={v|v=a row vector of BR₁ or BR₅}, A₂={v|v=a row vector of BR₂ or BR₆}, A₃={v|v=a row vector of BR₃ or BR₇}, A₄={v|v=a row vector of BR₄ or BR₉}, and also there are a 2*B number of weight one column vectors.

On the other hand, when P_{b} has the same structure as FIG. 1, k=7+B, Aᵢ={v|v=a row vector of BRᵢ}, where i=1, 2, . . . , 7, Aᵢ₊₇={v|v=a i^{th} row vector of BR₈}, where i=1, 2, . . . , B, and also there is one column vector with weight one in FIG. 3A. In FIG. 3B, k=3+B, A₁={v|v=a row vector of BR₁ or BR₅}, A₂={v|v=a row vector of BR₂ or BR₆}, A₃={v|v=a row vector of BR₃ or BR₇}, A₃+i={v|v=a i^{th} row vector of BR₄ or BR₈}, where i=1, 2, . . . , B and also there are two column vectors with weight one.

The encoding time is proportional to k. Additionally, the error correction performance of the parity check matrix deteriorates when the number of weight one column vectors increases. As described above, since k and the number of weight one column vectors can be controlled, it is desirable that an appropriate structure is selected considering the encoding time and the performance of H in the block structure.

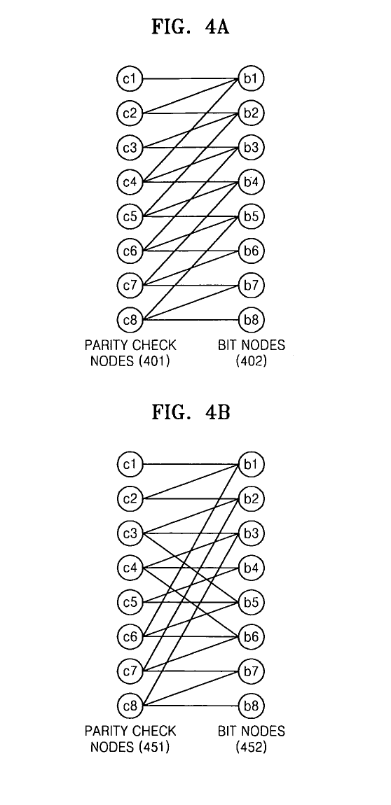

FIG. 4A is a diagram illustrating a connection between a parity check node 401 and a bit node 402 of a sub-matrix, Hₚ, in FIG. 1, according to an embodiment of the present invention. FIG. 4B is a diagram illustrating a connection between a parity check node 451 and a bit node 452 of a sub-matrix, Hₚ, in FIG. 2, according to another embodiment of the present invention.

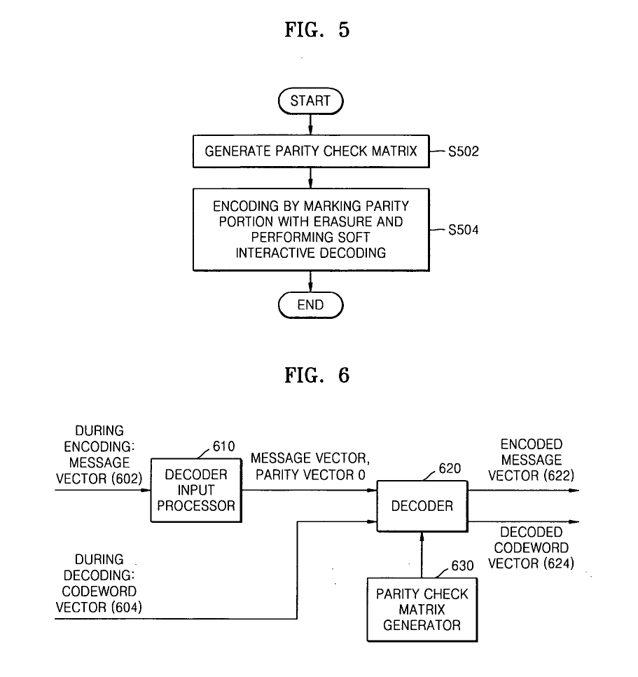

FIG. 5 is a flowchart illustrating an encoding method by decoding according to an embodiment of the present invention. Referring to FIG. 5, a parity check matrix, which satisfies the above-mentioned definition of an M×N matrix, H=[Hₘ|Hₚ], is generated in operation S502. A message vector is then encoded into a codeword vector by decoding using the generated parity check matrix. In operation S504, a soft iterative decoding can be used as the decoding method, and in this case, the soft iterative decoding method is performed by setting an entire parity portion to 0s. Since values of the parity part can be obtained through the decoding result, the encoding through the decoding is possible. However, as described below, the encoding is possible through the decoding in addition to the soft iterative decoding. The encoding method using the decoding will be described in more detail.

To perform the encoding with one decoder, information to determine whether the encoding or the decoding has been selected is received. When the encoding has been selected, the parity vector P(x) is obtained using an algebraic method or the soft iterative decoding method.

Let's assume that the parity check matrix is H=[Hₘ|Hₚ]. Here, Hₘ is an M×(N−M) sub-matrix. When an M dimension parity vector about the given N−M dimension message vector M(x) is P(x)=(P₁, P₂, . . . , P_{M}), a codeword vector C(x)−(M(x), P(x)) needs to satisfy HC^{T}=HₘM^{T}+HₚP_{T}=0 (M dimension zero vector). That is, a matrix product of all row vectors of H and C^{T} needs to be zero above the growth factor, GF(2). Consequently, when the M dimension parity vector satisfying HC^{T}=0 about the given M(x) is obtained, it indicates that the encoding is possible through the decoding.

First, the decoding process using the algebraic method will be explained. Firstly, let's assume that P₀(x)=(x₁, x₂, . . . , x_{M}). These values (x₁, x₂, . . . , x_{M}) are predetermined arbitrary values. At this point, C₀(x)=(M(x), P₀(x)). When using the algebraic method, M(x) can be encoded into C(x) by a k-step decoding.

Operation 1: performing the decoding by a set A₁.

A matrix product of a row vector of H, including row vectors in the set A₁, and C₀^{T} needs to be zero. Additionally, since the weight of the row vector in the set Al is one, an element xᵢ₁ of a parity vector P₀(x) corresponding to a value one element in the row vector obtains only solution Pᵢ₁ using a linear equation. As a result, P₀(x) is decoded into P₁(x)=(x₁, . . . , Pᵢ₁, x_{M}) by the set A₁. Let's assume that C₁(x)=(M(x), P₁(x)).

Operation 2: performing the decoding by a set A₂ with the decoding result of the operation 1.

A matrix product of a row vector of H, including row vectors in the set A₂, and C₁^{T} needs to be zero. Additionally, since the row vector in the set A₂ can generate a weight one row vector through a linear combination with row vectors in the set A₁, an element xᵢ₂ of a parity vector P₁(x) corresponding to a value one element in the row vector has only solution Pᵢ₂ by a linear equation. As a result, P₁(x) is decoded into P₂(x)=(x₁, . . . , Pᵢ₁, Pᵢ₂, . . . , x_{M}) by the set A₂. Let's assume that C₂(x)=(M(x), P₂(x)).

Operation k: performing the decoding by Aₖ with the decoding result of operation (k-1).

A matrix product of a row vector of H, including row vectors in the set Aₖ, and Cₖ₋₁^{T} needs to be zero. Additionally, since the row vector in the set Aₖ can generate a weight one row vector through a linear combination with row vectors in the A₁+A₁+ . . . +Aₖ₋₁, an element xᵢₖ of a parity vector Pₖ₋₁(x) corresponding to a value one element in the row vector has only solution Pᵢₖ by a linear equation. As a result, Pₖ₋₁(x) is decoded into P(x)=(P₁, P₂, . . . , P_{M}) by the set Aₖ. When C(x)=(M(x), P(x)), C(x) is an encoded codeword of M(x).

Second, an encoding method by the soft iterative decoding using a log likelihood ratio (LLR) like “MIN” approximation (approximation of a sum-product and a sum-product) will be explained.

In this case, when M(x) is converted into M′(x)=2*M(x)−1, and C′(x)=(M′(x), P′(x)) is inputted into the iterative decoder by setting P′(x)=0, C(x)=(M(x), P(x)) that satisfies HC^{T}=0 is decoded by at most a k number of the iteration. At this point, P′(x) is set to be 0s for an erasure mark because the encoding is performed using an erasure correction.

Since M′(x) does not contain any error, a value of the element is 1 or −1, and P′(x) is all 0s, the element values of P(x) corresponding to a position, where an element of a row vector in the set A₁ is 1, are corrected by a first correction because of the soft iterative decoding characteristics. When a result of the first correction is C₁(x), a correction is completed when HC₁^{T}=0; otherwise a second repetitive correction is performed. At this point, since a weight one row vector can be derived from row vectors of a set A₂ through a linear combination with the row vectors of the A₁, an element of the derived weight one row vector corrects an element value of P(x) corresponding to a position of weight one. When a result of the second correction is C₂(x), correction is completed when HC₂^{T}=0; otherwise a repetitive correction is performed. Through this method, all element values of P(x) are corrected by at least a kth correction. Consequently, C′(x) is corrected into C(x)=(M(x), P(x)) by at most a k number of iterative decoding. That is, the message vector M(x) is encoded into a codeword with the parity vector.

FIG. 6 is a configuration diagram of an error correction apparatus according to an embodiment of the present invention. The error correction apparatus includes a parity check matrix generator 630 generating an M×N parity check matrix, H, and a decoder 620 performing decoding using the generated parity check matrix H. The decoder 620 outputs an encoded message vector 622 by obtaining an M dimension parity vector to be added to an N−M dimension message vector 602 during encoding, and outputs a decoded codeword 624 after decoding the received codeword vector 604 during decoding. Additionally, when using a soft iterative decoder as the decoder 620, the error correction apparatus further includes a decoder input processor 610 to replace 0s in the inputted message vector 602 with −1s and to input a parity vector set with 0s into the decoder 620 during encoding.

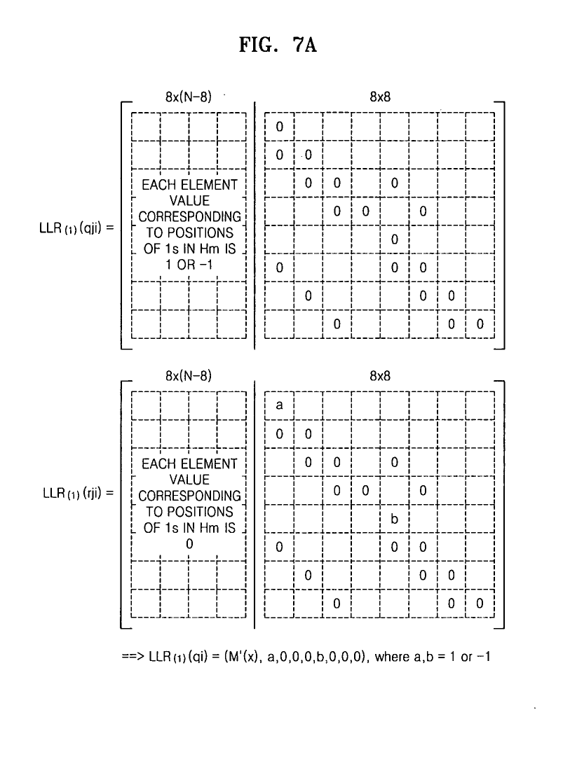

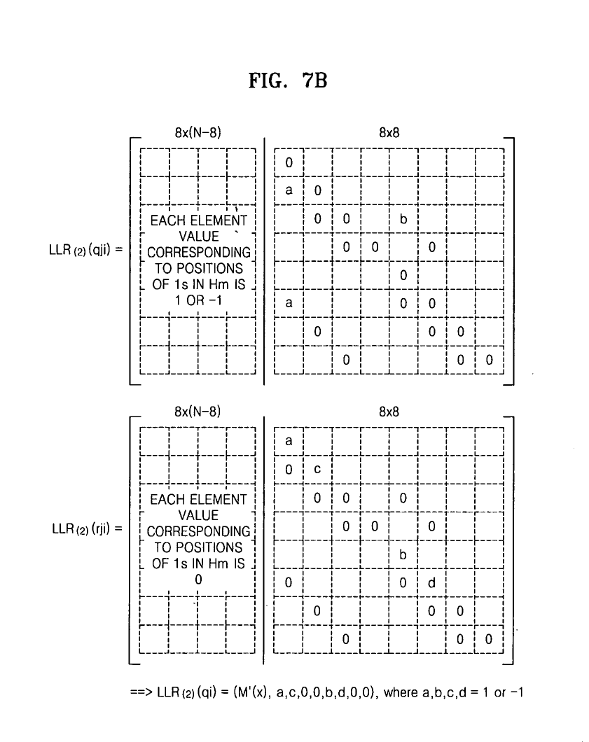

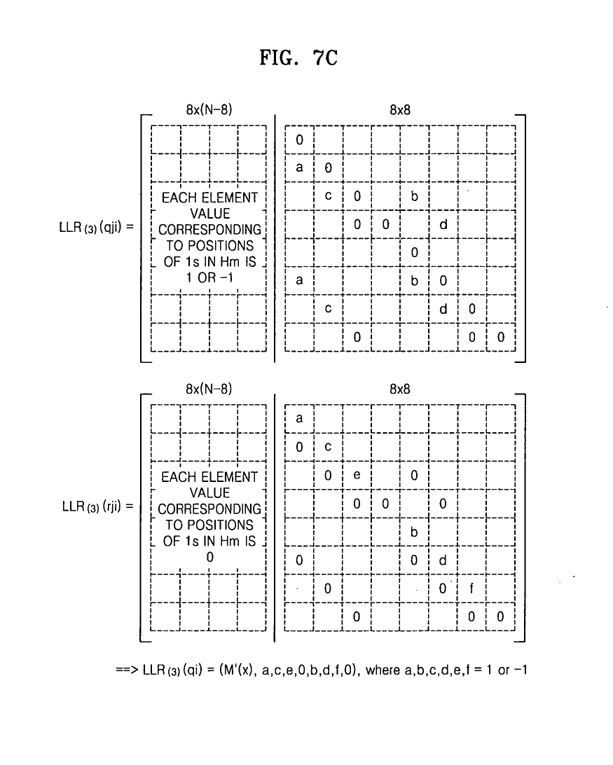

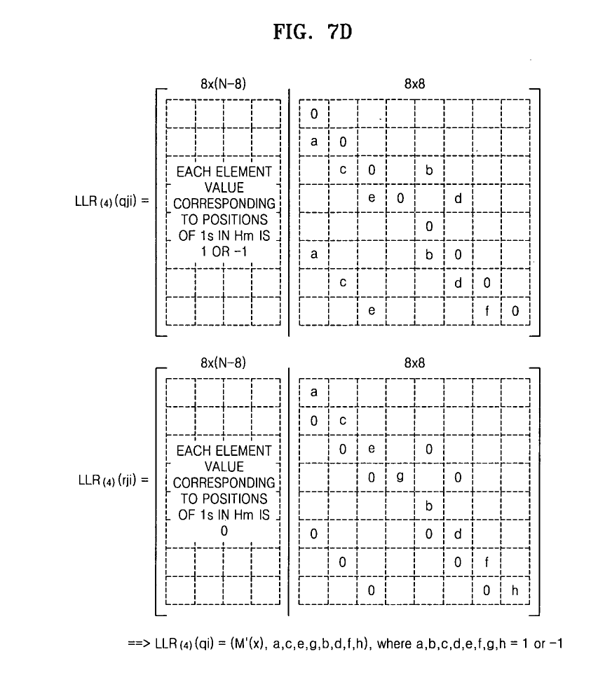

FIGS. 7A through 7D are diagrams explaining encoding processes through decoding according to an embodiment of the present invention. Through the illustrated processes, C(x) satisfying HC^{T}=0 is obtained using an encoding method through soft iterative decoding, and the soft iterative decoding is performed using the parity check matrix H of FIG. 2. First, let's input C′(x)=(2*M(x)−1,0) for the soft iterative decoding. That is, when the value of a message part of the codeword C′(x) is 1, the value 1 remains and when the value of the message portion is 0, the value 0 is changed into −1. Additionally, a parity portion is set to 0s for erasure correction, and then inputted into the soft iterative decoder.

FIG. 7A is a diagram illustrating a first correction process when C′(x)=(M′(x), 0, 0, 0, 0, 0, 0, 0, 0). When a hard decision result of LLR₍₁₎(qi) is C₁(x), the decoding is terminated when HC₁^{T}=0, and otherwise the correction is continued. FIG. 7B is a diagram illustrating a second correction process. When a hard decision result of LLR₍₂₎(qi) is C₂(x), the decoding is terminated when HC₂^{T}=0, and otherwise the correction is continued. FIG. 7C is a diagram illustrating a third correction process. When a hard decision result of LLR₍₃₎(qi) is C₃(x), the decoding is terminated when HC₃^{T}=0, and otherwise the correction is continued. FIG. 7D is a diagram illustrating a fourth correction process. When a hard decision result of LLR₍₄₎(qi) is C₄(x), HC₄^{T}=0 and the decoding is terminated because C₄(x) must be C(x). The reason that C₄(x) must be C(x) is that a, b, c, d, e, f, g, h values of the parity portion are set by the decoding algorithm so that a matrix product of Aᵢ (a row vector in each operation) and Cᵢ(x) becomes 0.

According to an embodiment of the present invention, since the encoding is possible through the decoding, the encoding and the decoding can be achieved with only one decoder for a parity check matrix.

The invention can also be embodied as computer-readable codes on a computer-readable recording medium.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A parity check matrix for an error correction and an encoding by decoding of data, wherein the parity check matrix is an M×N matrix, H=[Hₘ|Hₚ], where Hₘ is an M×(N−M) sub-matrix and Hₚ is an M×M sub-matrix comprising an M number of row vectors that are linearly independent, and a set A of the M number of the row vectors such that the-set A is a union set of subsets A₁, A₂, . . . , Aₖ, where 1≦k≦M, that do not comprise intersection sets with each other and are not empty sets, the subset A₁ is a set of weight one row vectors among the row vectors of the set A, and the subset Aᵢ, where 2≦i≦k, is a set of row vectors capable of deriving the weight one row vector by performing a linear combination with row vectors in a union set of the subsets A₁, . . . , Aᵢ₋₁ among row vectors not included in the union set of the subsets A₁, . . . , Aᵢ₋₁.

2. The parity check matrix as claimed in claim 1, wherein the parity check matrix does not comprise four cycles.

3. The parity check matrix as claimed in claim 1, wherein the parity check matrix has a block structure, M=8*B, where B is an integer greater than one, and the Hₚ comprises at least a B number of weight one column vectors.

4. The parity check matrix as claimed in claim 3, wherein the parity check matrix does not comprise four cycles.

5. A method of generating a parity check matrix for an error correction and an encoding by decoding of data, the method comprising:
defining an M×N parity check matrix, H=[Hₘ|Hₚ]; and
generating an M×M sub-matrix, Hₚ, of the parity check matrix H, comprising an M number of row vectors that are linearly independent, a set A of the M number of the row vectors such that the set A is a union set of subsets A₁, A₂, . . . , Aₖ, where 1≦k≦M, that do not comprise intersection sets with each other and are not empty sets, the subset A₁ is a set of weight one row vectors among the row vectors of the set A, and the subset Aᵢ, where 2≦i≦k, is a set of row vectors capable of deriving the weight one row vector by performing a linear combination with row vectors in a union set of the subsets A₁, . . . , Aᵢ₋₁ among row vectors not included in the union set of the subsets A₁, . . . , Aᵢ₋₁,.

6. The method as claimed in claim 5, further comprising removing four cycles from the parity check matrix.

7. The method as claimed in claimed in claim 5, wherein the defining of the M×N parity check matrix comprises defining the parity check matrix to have a block structure, wherein M=8*B, where B is an integer greater than one; and
the generating of the M×M sub-matrix Hₚ comprises generating at least a B number of weight one column vectors in the sum-matrix Hₚ.

8. The method as claimed in claim 7, further comprising removing four cycles from the parity check matrix.

9. A method of encoding an N−M dimension data message vector, the encoding method comprising:
generating an M×N parity check matrix, H=[Hₘ|Hₚ], by generating an M×M sub-matrix, Hₚ, of the parity check matrix H, comprising an M number of row vectors that are linearly independent, a set A of the M number of the row vectors such that the set A is a union set of subsets A₁, A₂, . . . , Aₖ, where 1≦k≦M, that do not include intersection sets with each other and are not empty sets, the subset A₁ is a set of weight one row vectors among the row vectors of the set A, and a subset Aᵢ (2≦i≦k) is a set of row vectors capable of deriving the weight one row vector by performing a linear combination with row vectors in a union set of the subsets A₁, . . . , Aᵢ₋₁ among row vectors not included in the union set of the subsets A₁, . . . , Aᵢ₋₁; and
encoding the message vector by adding a parity vector having an M dimension thereto through decoding using the generated parity check matrix.

10. The method as claimed in claim 9, wherein the generating of the M×N parity check matrix comprises removing four cycles from the parity check matrix.

11. The method as claimed in claim 9, wherein the generating of the M×N parity check matrix comprises:
defining the parity check matrix to have a block structure, wherein M=8*B, where B is an integer greater than one; and
generating at least a B number of weight one column vectors in the sub-matrix Hₚ.

12. The method as claimed in claim 11, wherein the generating of the M×N parity check matrix comprises removing four cycles from the parity check matrix.

13. The method as claimed in claim 9, wherein the encoding of the message vector comprises marking the parity vector with an erasure mark, wherein the encoding is performed using an erasure correction and the decoding is a soft iterative decoding method.

14. The method as claimed in claim 13, wherein the marking of the parity vector with the erasure mark comprises setting the entire parity vector with 0s when the decoding.

15. The method as claimed in claim 13, wherein the encoding of the message vector further comprises replacing 0s of the message vector with −1s.

16. A method of encoding an N−M dimension data message vector, the encoding method comprising:
generating an M×N parity check matrix, H=[Hₘ|Hₚ], by generating an M×M sub-matrix, Hₚ, of the parity check matrix H, comprising an M number of row vectors that are linearly independent, a set A of the M number of the row vectors such that the set A is a union set of subsets A₁, A₂, . . . , Aₖ, where 1≦k≦M, that do not include intersection sets with each other and are not empty sets, the subset A₁ is a set of weight one row vectors among the row vectors of the set A, and a subset Aᵢ (2≦i≦k) is a set of row vectors capable of deriving the weight one row vector by performing a linear combination with row vectors in a union set of the subsets A₁, . . . , Aᵢ₋₁ among row vectors not included in the union set of the subsets A₁, . . . , Aᵢ₋₁; and
encoding the message vector by setting an entire parity vector with 0s, replacing 0s of the message vector with −1s, and adding the parity vector having an M dimension to the message vector through soft-iterative decoding using the generated parity check matrix.

17. The method as claimed in claim 16, wherein the generating of the M×N parity check matrix comprises removing four cycles from the parity check matrix.

18. The method as claimed in claim 16, wherein the generating of the M×N parity check matrix comprises:
defining the parity check matrix to have a block structure, wherein M=8*B, where B is an integer greater than one; and
generating at least a B number of weight one column vectors in the sub-matrix Hₚ.

19. The method as claimed in claim 18, wherein the generating of the M×N parity check matrix comprises removing four cycles from the parity check matrix.

20. An error correction apparatus comprising:
a matrix generator to generate an M×N parity check matrix, H=[Hₘ|Hₚ], where Hₘ is an M×(N−M) sub-matrix and Hₚ is an M×M sub-matrix comprising an M number of row vectors that are linearly independent, and a set A of the M number of the row vectors such that the set A is a union set of subsets A₁, A₂, . . . , Aₖ, where 1≦k≦M, that do not comprise intersection sets with each other and are not empty sets, the subset A₁ is a set of weight one row vectors among the row vectors of the set A, and the subset Aᵢ, where 2≦i≦k, is a set of row vectors capable of deriving the weight one row vector by performing a linear combination with row vectors in a union set of the subsets A₁, . . . , A₁₋₁ among row vectors not included in the union set of the subsets A₁, . . . , Aᵢ₋₁; and
a decoder to encode a message vector of an N−M dimension by adding a parity vector having an M dimension to the message vector through decoding using the generated parity check matrix, and to decode a received codeword vector.

21. The error correction apparatus as claimed in claim 20, further comprising a decoder input processor to replace 0s of the message vector with −1s , and to output the message vector with the replaced 0s into the decoder, wherein the parity vector is set entirely with 0s and the decoder is a soft iterative decoder.

22. The error correction apparatus as claimed in claim 20, wherein the parity check matrix does not comprise four cycles.

23. The error correction apparatus as claimed in claim 20, wherein the parity check matrix has a block structure, M=8*B, where B is an integer greater than one, and the Hₚ comprises at least a B number of weight one column vectors.

24. The error correction apparatus as claimed in claim 23, wherein the parity check matrix does not comprise four cycles.

25. An error correction apparatus comprising:
a matrix generator to generate an M×N parity check matrix, H=[Hₘ|Hₚ], where Hₘ is an M×(N−M) sub-matrix and Hₚ is an M×M sub-matrix comprising an M number of row vectors that are linearly independent, and a set A of the M number of the row vectors such that the set A is a union set of subsets A₁, A₂, . . . , Aₖ, where 1≦k≦M, that do not comprise intersection sets with each other and are not empty sets, the subset A₁ is a set of weight one row vectors among the row vectors of the set A, and the subset Aᵢ, where 2≦i ≦k, is a set of row vectors capable of deriving the weight one row vector by performing a linear combination with row vectors in a union set of the subsets A₁, . . . , Aᵢ₋₁, among row vectors not included in the union set of the subsets A₁, . . . , Aᵢ;
a decoder to encode a message vector of an N−M dimension by adding a parity vector having an M dimension and set entirely with 0s to the message vector through soft-iterative decoding using the generated parity check matrix, and to decode a received codeword vector; and
a decoder input processor to replace 0s of the message vector with −1s , and to output the message vector with the replaced 0s into the decoder.

26. The error correction apparatus as claimed in claim 25, wherein the parity check matrix does not comprise four cycles.

27. The error correction apparatus as claimed in claim 25, wherein the parity check matrix has a block structure, M=8*B, where B is an integer greater than one, and the Hₚ comprises at least a B number of weight one column vectors.

28. The error correction apparatus as claimed in claim 27, wherein the parity check matrix does not comprise four cycles.

29. A computer readable recording medium encoded with the method of claim 5 implemented by a computer.

30. A computer readable recording medium encoded with the method of claim 9 implemented by a computer.

31. A computer readable recording medium encoded with the method of claim 16 implemented by a computer.
